(19) United States
(12) Patent Application Publication
(10) Pub. No.: US 2004/0227219 A1
(43) Pub. Date: Nov. 18, 2004

(54) Intelligent tag for glasses

(76) Inventor: Chi-Yang Su, Chung-Ho (TW)

Correspondence Address: Ann Tsai, Suite 137, PmB 174, 931 West 75th Street, Naperville, IL, 60565, US

(21) Appl. No.: 10/842,529

(22) Filed: May 11, 2004

(30) Foreign Application Priority Data
May 13, 2003 (TW) 092208826

(51) Int. Cl. H01L 23/02

(52) U.S. Cl. 257/679

(57) ABSTRACT

An intelligent tag for glasses is composed of a chip, a coil and a printed circuit board and the intelligent tag is joined to or embedded to the glasses. The chip is provided with an internal memory and the internal memory is recorded with digital data, which is encoded from messages with regard to a company making the glasses and personal data of a wearer of the glasses, by way of wireless induction burning technique. The digital data can be read out and decoded with a reader by way of wireless accessing and the decoded messages can be sent to a personal computer for further use.

### BACKGROUND OF THE INVENTION

1. Field of the Invention

The present invention is related to an intelligent tag for glasses and particularly to an intelligent tag, which can be recorded with and read out digital data with regard to messages of the glasses by way of wireless burning and wireless read accessing.

2. Brief Description of Related Art

Conventionally, message with regard to glasses such as manufacturer name, lot number, date of production and etc. usually is printed on a label and the label is attached to the glasses. Due to limited size of the label, it is not possible to indicate much information and it is very easy to be copied. Further, it is tedious to renew the label in case of the information being updated.

In addition, messages related to the wearer of the glasses such as near-sighted data usually are stored in a personal computer of the glasses selling store. Once the glasses are repaired at another glasses store, it is hard to obtain the original data unless an optometry is conducted again. That is, the original near-sighted data is not possible carried with the wearer at all times to result in inconvenience.

### SUMMARY OF THE INVENTION

An object of the present invention is to provide an intelligent tag for glasses with which message related to the manufacturer of the glasses can be repeatedly input and read out easily.

Another object of the present invention is provide an intelligent tag for glasses with which personal data of the wearer can be repeatedly input and read out easily.

A further object of the present invention the message related to the glasses manufacturer and personal data of the wearer can be moved with the glasses.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of the first embodiment for the intelligent tag according to the present invention;

FIG. 2 is a perspective view illustrating the intelligent tag shown in FIG. 1 being attached to glasses;

FIG. 3 is a flow chart for operating the intelligent tag of the present invention;

FIG. 4 is a perspective view of the second embodiment for the intelligent tag according to the present invention; and

FIG. 5 is a perspective view of the third embodiment for the intelligent tag according to the present invention.

### DETAILED DESCRIPTION OF THE PREFERRED EMBODIMENTS

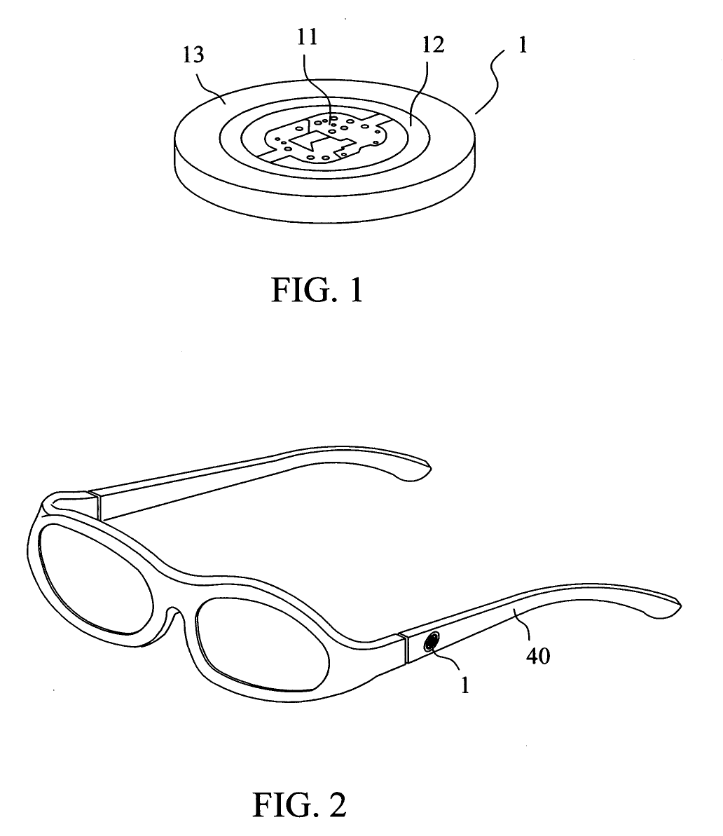

Referring to FIG. 1, an intelligent tag 1 on eyeglasses according to the present invention includes a chip 11, a coil 12 and a base plate 13. The coil 12 is provided with an annular shape and the chip 10 is placed in the coil 12. Two pins are disposed at two opposite sides of the chip 11 to electrically connect with the coil 12. After the chip 11 and the coil 12 being assembled, the assembly is inserted into the base plate 13, which surrounds the coil 12. It is preferable that the radius of the completed tag 1 is less than 15 mm with a thickness less than 0.4 mm.

Referring to FIG. 2, the completed tag 1 can be attached to an appropriate spot of glasses 4 with one of attaching ways such as gluing, screw fastening and the like. Messages related to the manufacturer of the glasses such as the manufacturer's name, lot number, production date and etc and personal data of the wearer can be encoded as digital data. Further, the digital data can be recorded in an internal memory of the chip 11 by way of wireless induction burning technique. A reader can be used to read out and decode the digital data by way of wireless reading and the decoded data can be sent to a personal computer for further use. Hence, the procedure of recognition for the data is completed.

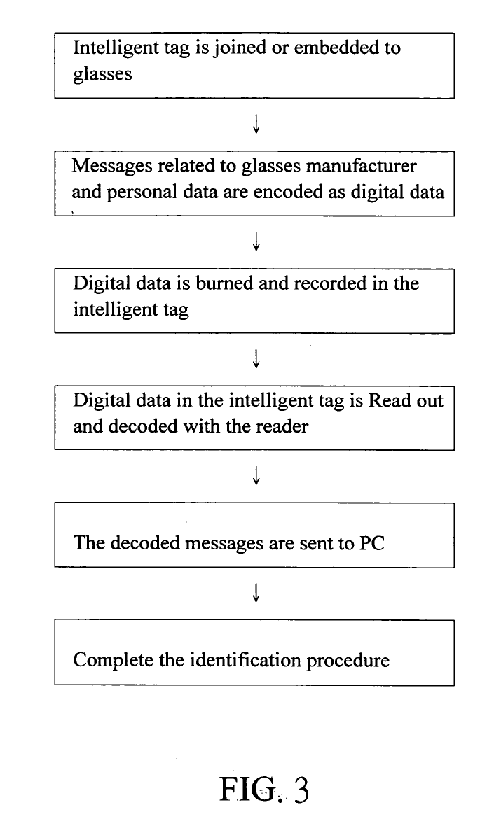

Referring to FIG. 3, a flow chart of operation for the procedure of recognition is illustrated and the steps are explained in the following: (1) the intelligent tag is joined or embedded to the glasses; (2) the messages with regard to the glasses company and personal data are encoded as digital data; (3) the digital data are recorded in the internal memory of the tag by way of wireless induction burning technique; (4) the digital data in the intelligent tag is read out and decoded with a reader by way of wireless accessing; (5) the decoded message is sent to a personal computer for further use. It is very important that the preceding steps for encoding and decoding the digital data can be processed repeatedly so that the stored message can be renewed or changed.

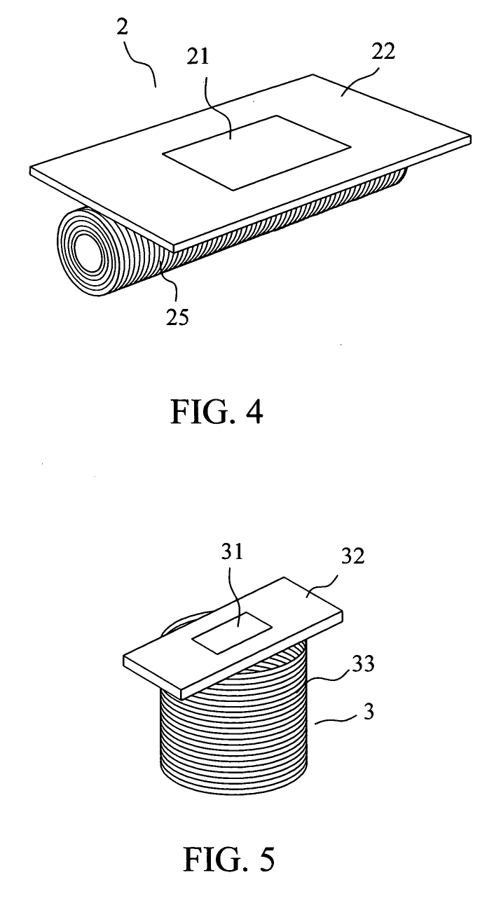

Referring to FIG. 4, a second embodiment of the intelligent tag according to the present invention is illustrated. The intelligent tag 2 is provided with a rectangular shaped chip 21 attached to a print circuit board 22. Then, the print circuit board 22 at the bottom thereof is joined to the circumferential side of an slender cylindrical coil 25. It is preferable that the intelligent tag 2 has a length not exceeding 1 cm with a thickness less than 0.4 mm. The intelligent tag 2 is embedded at a suitable spot of the glasses such as glasses arms, bent ends of the glasses arms and nose supports. Then, messages with regard to the company of the glasses and personal data are encoded as digital data and the digital data is recorded in an internal memory of the intelligent tag 2. As for operation to identify the glasses, it is the same as the procedure shown in FIG. 3, which has been explained for the first embodiment previously, and no detail will be described further.

Referring to FIG. 5, the third embodiment is illustrated. The intelligent tag 3 is similar to the second embodiment and has a chip 31 is joined to a print circuit board 32. The bottom of the print circuit board 32 is attached to an end of a coil 33. The present embodiment is a variation of the second embodiment.

It is appreciated that the intelligent tag according to the present invention can be joined to or embedded to a pair of glasses with the messages with regard to the company of glasses and personal data being recorded in the chip of the tag by way of encoded as digital data, which is further burned in the internal memory with wireless induction technique. The digital data can be decoded with a reader and sent to a personal computer for further use.

While the invention has been described with referencing to preferred embodiments thereof, it is to be understood that modifications or variations may be easily made without departing from the spirit of this invention, which is defined by the appended claims.

What is clamed is:

1. An intelligent tag for glasses, comprising:
a chip, being provided with two opposite connecting pins;
a coil, being provided with an annular shape, receiving the chip and electrically connecting with the connecting pins;
a base plate, being inserted with the coil;
whereby, the intelligent tag can be joined to the glasses.

2. The intelligent tag as defined in claim 1, wherein the intelligent tag preferably provides a diameter less than 15 mm and a thickness less than 0.4 mm.

3. The intelligent tag as defined in claim 1, wherein the chip is provided with an internal memory and the internal memory is recorded with digital data, which is encoded from messages with regard to a company making the glasses and personal data of a wearer of the glasses, by way of wireless induction burning technique.

4. The intelligent tag as defined in claim 3, wherein the digital data can be read out and decoded with a reader by way of wireless accessing and the decoded messages can be sent to a personal computer for further use.

5. An intelligent tag for glasses, comprising:
a chip;
a printed circuit board, being joined with the chip; and
a coil, being attached with the printed circuit board;
wherein, the intelligent tag can be embedded to the glasses.

6. The intelligent tag as defined in claim 5, wherein the intelligent tag preferably provides a length less than lcm and a thickness less than 0.4 mm.

7. The intelligent tag as defined in claim 5, wherein the printed circuit at the bottom thereof is attached to the circumference side of the coil.

8. The intelligent tag as defined in claim 5, wherein the printed circuit at the bottom thereof is attached to an end of the coil.

9. The intelligent tag as defined in claim 5, wherein the chip is provided with an internal memory and the internal memory is recorded with digital data, which is encoded from messages with regard to a company making the glasses and personal data of a wearer of the glasses, by way of wireless induction burning technique.

10. The intelligent tag as defined in claim 5, wherein the digital data can be read out and decoded with a reader by way of wireless accessing and the decoded messages can be sent to a personal computer for further use.
